(19) United States
(12) Patent Application Publication
(10) Pub. No.: US 2026/0110977 A1
(43) Pub. Date: Apr. 23, 2026

(54) STORAGE MEDIUM, INFORMATION PROCESSING APPARATUS, SUBSTRATE PROCESSING APPARATUS, AND ARTICLE MANUFACTURING METHOD

(71) Applicant: CANON KABUSHIKI KAISHA, Tokyo (JP)

(72) Inventor: RYOJI ASAHI, Tochigi (JP)

(21) Appl. No.: 19/354,172

(22) Filed: Oct. 9, 2025

(30) Foreign Application Priority Data
Oct. 17, 2024 (JP) 2024-182173

(51) Int. Cl. G03F 7/00

(52) U.S. Cl. CPC G03F 7/706845; G03F 7/70508

(57) ABSTRACT

A computer-readable storage medium storing a program for causing a computer to execute an adjustment method of adjusting apparatus performance of a substrate processing apparatus. The program causes the computer to perform acquiring an adjustment result indicating a result of a first adjustment process executed in the substrate processing apparatus, estimating a result of a second adjustment process performed after the first adjustment process in the substrate processing apparatus based on an apparatus specification of the substrate processing apparatus, and determining a condition for the second adjustment process based on the adjustment result and an estimation result obtained in the estimating.

### BACKGROUND

### FIELD OF THE TECHNOLOGY

The present disclosure relates to a storage medium, an information processing apparatus, a substrate processing apparatus, and an article manufacturing method.

### DESCRIPTION OF THE RELATED ART

Devices are manufactured by using a substrate processing apparatus that transfers the patterns of original plates onto substrates. The substrate processing apparatus is, for example, an exposure apparatus that makes a projection optical system project and transfer the circuit pattern drawn on an original plate onto a substrate by using a photolithography technique. Operations to be done after the assembly of an exposure apparatus include an adjusting operation for the apparatus, a checking operation for the adjustment, and an installing operation. In these operations, after inspection items are determined in accordance with apparatus configurations, the operator performs operations corresponding to the inspection items for the exposure apparatus and determines whether the apparatus meets standards.

Japanese Patent Laid-Open No. 2003-059811 discloses that in an adjustment checking operation for an exposure apparatus, a plurality of processes are sequentially executed in accordance with a plurality of operation details.

As the time of an adjustment checking operation is shortened, the apparatus can be shipped out in a shorter period of time. In order to shorten the time of an adjustment checking operation, the number of inspection items may be reduced. Uniformly reducing inspection items can lead to a deterioration in apparatus quality.

### SUMMARY

The present disclosure provides a technique advantageous in satisfying both requirements for a reduction in time associated with an adjustment checking operation performed at the time of assembly or maintenance of a substrate processing apparatus and apparatus quality.

The present disclosure in its one aspect provides a computer-readable storage medium storing a program for causing a computer to execute an adjustment method of adjusting apparatus performance of a substrate processing apparatus, the program causing the computer to perform acquiring an adjustment result indicating a result of a first adjustment process executed in the substrate processing apparatus, estimating a result of a second adjustment process performed after the first adjustment process in the substrate processing apparatus based on an apparatus specification of the substrate processing apparatus, and determining a condition for the second adjustment process based on the adjustment result and an estimation result obtained in the estimating.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing the arrangement of an exposure apparatus;

FIG. 2 is a view showing the arrangement of an alignment optical system;

FIG. 3 is a view showing an example of apparatus specifications;

FIG. 4 is a flowchart showing an adjustment process for the apparatus performance of the exposure apparatus;

FIG. 5 is a flowchart showing a data collection process;

FIG. 6 is a graph showing the relative differences between the measurement results obtained by an alignment scope;

FIG. 7 is a graph representing standard deviations 3σ with respect to a plurality of plots shown in FIG. 6; and

FIG. 8 is a flowchart showing an adjustment process for the apparatus performance of the exposure apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### FIRST EMBODIMENT

The present disclosure relates to a substrate processing apparatus that processes a substrate. The substrate processing apparatus is, for example, an apparatus that performs the process of forming a pattern on a substrate. This apparatus can be, for example, a lithography apparatus, such as an exposure apparatus or an imprint apparatus, which forms a pattern on a substrate. The following description is based on the assumption that the substrate processing apparatus according to the present disclosure is an exposure apparatus that is an example of a lithography apparatus.

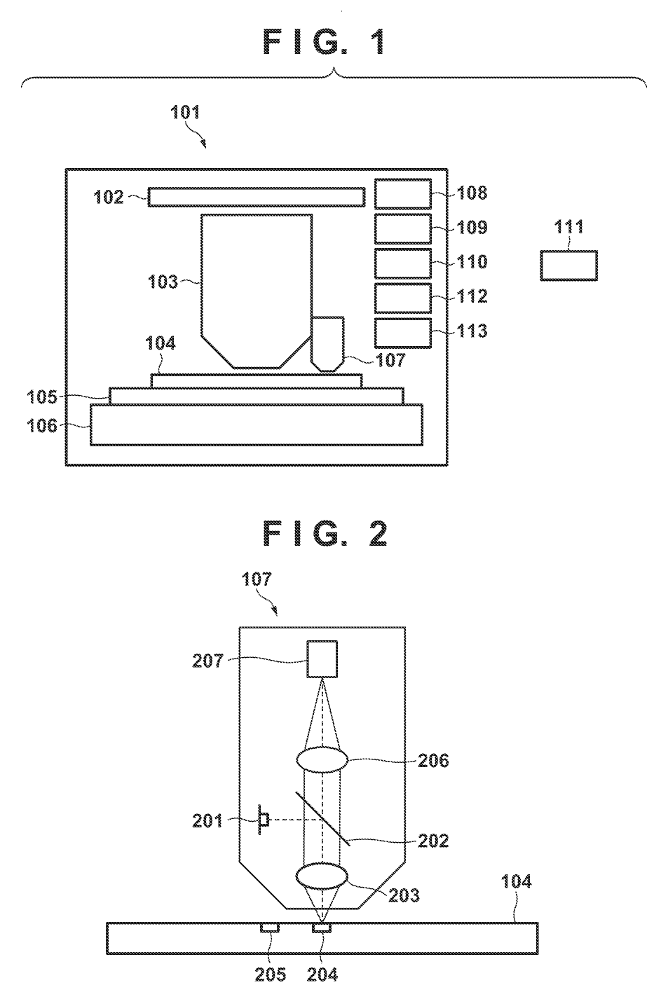

FIG. 1 shows the arrangement of an exposure apparatus 101 according to an embodiment. The exposure apparatus 101 is a lithography apparatus used in a manufacturing step for a device such as a semiconductor device. The exposure apparatus 101 projects the pattern of an original plate 102 (which can also be called a reticle or mask) onto a substrate 104 through a projection optical system 103 and exposes the substrate 104 to light. As shown in FIG. 1, the exposure apparatus 101 includes the projection optical system 103 that projects (reduced projection) the pattern formed on the original plate 102 and a chuck 105 that holds the substrate 104 on which an underlying pattern and alignment marks are formed in preceding steps.

The exposure apparatus 101 includes a substrate stage 106 that holds the chuck 105 and positions the substrate 104 at a predetermined position, an alignment optical system 107 that measures the position of an alignment mark provided on the substrate 104, and a controller 108. The controller 108 is formed of a computer (information processing apparatus) including a CPU and a memory and comprehensively controls the respective units of the exposure apparatus 101 in accordance with the programs stored in a storage unit 109 and the like. The storage unit 109 stores programs, various types of information (data), and the like that are required to execute the exposure process of exposing the substrate 104 to light by controlling the respective units of the exposure apparatus 101.

A collection unit 110 collects various types of information (data) stored in the storage unit 109 and transfers the information to an external collection unit 111. The collection unit 110 also collects information about a plurality of exposure apparatuses (a plurality of substrate processing apparatuses) which is stored in the external collection unit 111. In the present embodiment, the collection unit 110 collects apparatus specification data indicating the specification of the exposure apparatus 101 which is stored in the storage unit 109 and an adjustment result indicating the result of the first adjustment process for the apparatus performance. An estimation unit 112 generates the estimated data of an exposure adjustment result (to be described later). A determination unit 113 evaluates the estimated data obtained by the estimation unit 112 and determines a condition for the second adjustment process for the apparatus performance based on the evaluation result. Note that the controller 108 may implement the functions of the collection unit 110, the estimation unit 112, and the determination unit 113. The storage unit 109 may be a storage device provided inside or outside the controller 108. The controller 108 as an information processing apparatus may be provided inside or outside the exposure apparatus.

FIG. 2 shows the arrangement of the alignment optical system 107. The alignment optical system 107 has a function of acquiring position measurement data by optically detecting the alignment mark assigned to each shot region of the substrate 104. The alignment optical system 107 includes a light source 201, a beam splitter 202, a lens 203, a lens 206, and a sensor 207. Light from the light source 201 is reflected by the beam splitter 202 and illuminates a pre-alignment mark 204 or a fine alignment mark 205 provided on the substrate 104 through the lens 203. The light diffracted by the pre-alignment mark 204 or the fine alignment mark 205 is received by the sensor 207 through the lens 203, the beam splitter 202, and the lens 206.

As the time of an adjustment checking operation (to be referred to as an "adjustment process" hereinafter) performed at the time of assembly or maintenance of an exposure apparatus is shortened, the exposure apparatus can be shipped out in a shorter period of time. In order to shorten the time of an adjustment process, the number of inspection items may be reduced. Uniformly reducing inspection items can lead to a deterioration in apparatus quality. Of the inspection items, an inspection involving exposure in particular requires a long operation time. This is because it is necessary to prepare materials such as an original plate and a substrate and perform a projection process using a light source (laser or the like). This is also because it is necessary in some case to perform a substrate transfer process for the execution of a developing process and the measurement of an exposure result by using apparatuses other than the exposure apparatus. In addition, an inspection involving exposure requires many physical resources such as a laser light source and chemicals and the like used in a developing process as compared with an inspection involving no exposure (inspection without exposure). The following embodiment is configured to solve such problems.

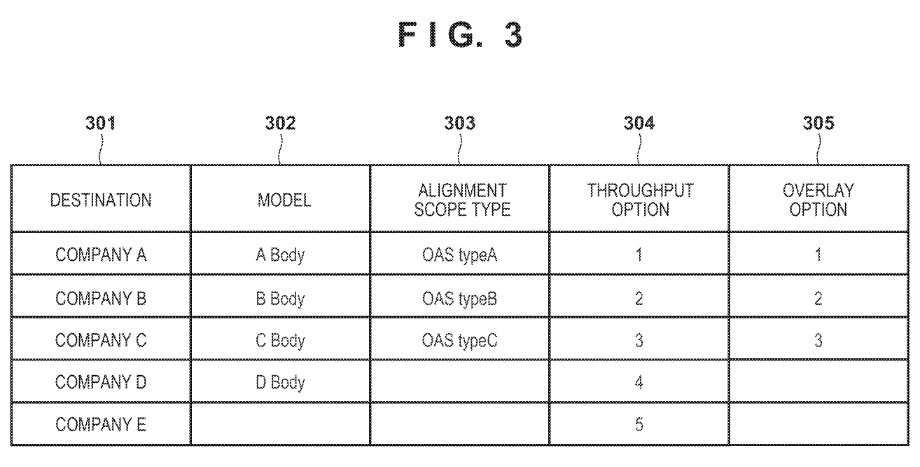

FIG. 3 shows an example of apparatus specifications indicating the specifications of exposure apparatuses. A destination 301 represents the destination customer name of the exposure apparatus 101. A model 302 represents the model type of the exposure apparatus 101. An alignment scope type 303 represents the type of the alignment optical system 107 mounted on the apparatus. A throughput option 304 represents the type of productivity improvement option set in the controller 108 based on the arrangement of the substrate stage 106 and the like. An overlay option 305 represents the type of overlay accuracy improvement option set in the controller 108 based on the arrangement of the alignment optical system 107 and the like. Note that the apparatus specification items shown in FIG. 3 are only exemplary and are not limited to them.

The apparatus specification of the exposure apparatus is uniquely determined by a combination of the destination 301, the model 302, the alignment scope type 303, the throughput option 304, and the overlay option 305. The exposure apparatus 101 stores its own apparatus specification in the storage unit 109. For example, focus on the combination on the first row in FIG. 3. The apparatus specification includes the following:

destination 301: company A

model 302: A Body

alignment scope type 303: OAS type A

throughput option 304: 1

overlay option 305: 1

The apparatus specification including this combination is specified by, for example, "α1". The combination on the second row is specified by, for example, "α2".

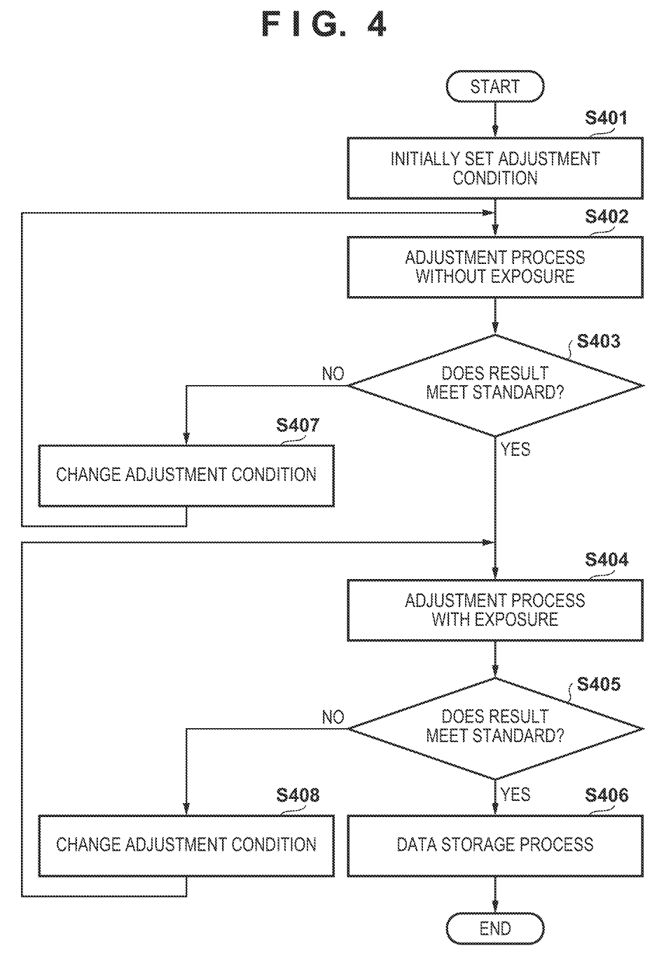

Adjustment processing for the apparatus performance of the exposure apparatus will be described with reference to the flowchart of FIG. 4. This process is performed at the time of, for example, assembly or maintenance of the exposure apparatus. Note that the process is different from adjustment or the like of characteristic parameters at the time of device production (normal operation). As will be described later, the result of this adjustment process is stored in the storage unit 109. Accordingly, executing this adjustment process using a plurality of exposure apparatuses having different apparatus specifications will accumulate the results of the adjustment processes with the plurality of apparatus specifications.

In step S401, the controller 108 initially sets an adjustment condition in accordance with the apparatus specification of the exposure apparatus 101 stored in the storage unit 109. The adjustment condition can include adjustment parameter values for the exposure apparatus. For example, the controller 108 can initially set an adjustment condition by referring to a lookup table describing the correspondence relationship between apparatus specifications and adjustment conditions stored in advance in the storage unit 109. For example, if the exposure apparatus 101 has an apparatus specification α1, the controller 108 refers to the lookup table to initially set a measurement condition β1 for the installation error of the alignment optical system 107 as an adjustment condition corresponding to the apparatus specification α1.

In step S402, the controller 108 executes an adjustment process without exposure in accordance with the adjustment condition initially set in step S401. The adjustment process without exposure is an adjustment process without any exposure process. For example, checking and adjustment processes for the measurement accuracy of the alignment optical system 107 are adjustment processes without exposure.

In step S403, the controller 108 determines whether the result of the adjustment process without exposure in step S402 (for example, the measurement error value obtained from the alignment optical system 107) meets a predetermined standard (inside an allowable range). If the result of the adjustment process without exposure does not meet the standard, the controller 108 changes the adjustment condition in step S407 and executes an adjustment process without exposure again in step S402. Assume that a standard corresponding to the measurement condition β1 is represented by γ1. In this case, if the result of the adjustment process without exposure does not meet the standard, the controller 108 changes the measurement condition to β2 and also changes the standard to γ2. In this state, the controller 108 performs an adjustment process again. If the result of the adjustment process without exposure meets the standard, the process advances to step S404.

In step S404, the controller 108 executes an adjustment process with exposure in accordance with the adjustment condition initially set in step S401. The adjustment process with exposure is an adjustment process involving an exposure process. For example, an adjustment process with exposure includes checking and adjustment of the overlay accuracy when the pattern of the original plate 102 is projected onto the substrate 104 through the projection optical system 103.

In step S405, the controller 108 determines whether the result of the adjustment process with exposure executed in step S404 (for example, the overlay error value between the original plate and the substrate) meets a predetermined standard (within an allowable range). If the result of the adjustment process with exposure does not meet the standard, the controller 108 changes the adjustment condition in step S408 and performs again an adjustment process with exposure in step S404. If the result of the adjustment process with exposure meets the standard, the process advances to step S406.

In step S406, the controller 108 saves, in the storage unit 109, the adjustment result as a set of the apparatus specification, the adjustment condition set finally, the result of the adjustment process without exposure, and the result of the adjustment process with exposure. Thereafter, the collection unit 110 transfers the adjustment result stored in the storage unit 109 to the external collection unit 111.

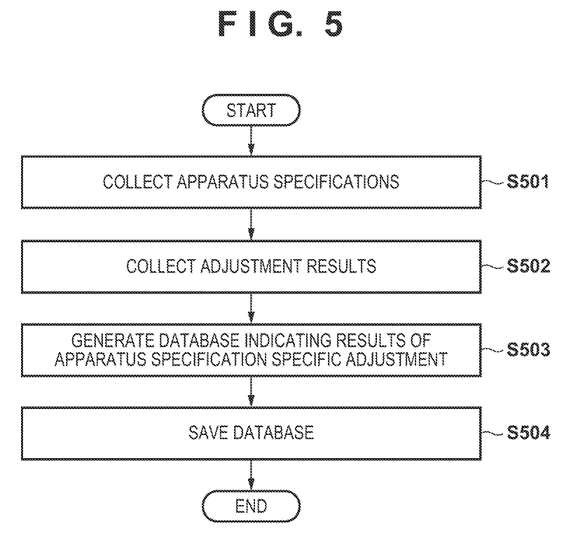

The data collection process performed by the collection unit 110 will be described with reference to the flowchart of FIG. 5. In step S501, the collection unit 110 collects a plurality of apparatus specifications associated with a plurality of exposure apparatuses from the external collection unit 111 (first collection step). In step S502, the collection unit 110 collects the results of a plurality of adjustment processes without exposure and the results of a plurality of adjustment processes with exposure from the external collection unit 111 (second collection step). In this case, "the results of a plurality of adjustment processes without exposure" is a set of the results of adjustment processes without exposure respectively corresponding to a plurality of apparatus specifications, and "the results of a plurality of adjustment processes with exposure" is a set of the results of adjustment processes with exposure respectively corresponding to a plurality of apparatus specifications. In step S503, the controller 108 generates a database indicating the results of apparatus specification specific adjustment processes with and without exposure based on the data collected in steps S501 and S502 (generating step). That is, the database is obtained based on the actual results of adjustment processes with and without exposure performed by a plurality of exposure apparatuses with different apparatus specifications and indicates the results of the apparatus specification specific adjustment processes with and without exposure. The database includes, for example, data indicating the correspondence among the apparatus specification α1, a result x1 of an adjustment process without exposure under the apparatus specification α1, and a result x2 of an adjustment process with exposure under the apparatus specification α1. In step S504, the controller 108 stores the generated database in the storage unit 109. In this case, if the adjustment result under the same apparatus specification is already stored in the database, the controller 108 may overwrite (update) the latest adjustment result in correspondence with the same apparatus specification as that has already been stored. Alternatively, the apparatus specification may be updated with the data obtained by averaging the adjustment result under the same apparatus specification as that has already been stored and the latest adjustment result.

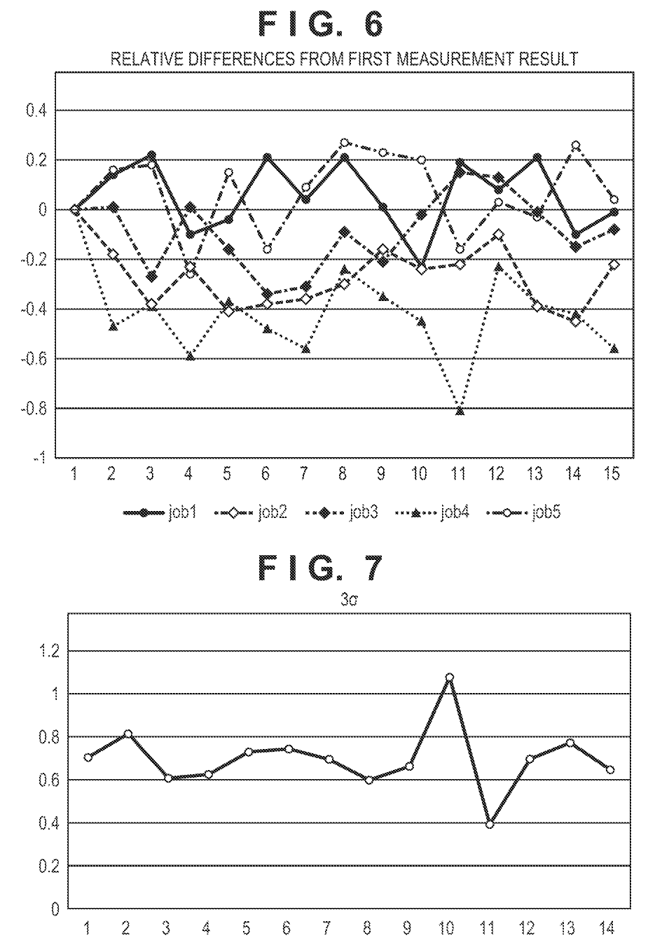

FIG. 6 is a graph showing an example of the relative differences between the measurement results obtained by the alignment optical system 107 in jobs obtained by the adjustment process without exposure in step S402. FIG. 6 shows plots corresponding to five jobs represented by Jobs 1 to 5. The abscissa represents the measurement count (15 in the case shown in FIG. 6) per job, and the ordinate represents the relative distances [nm] with respect to the first measurement value. The relative distances indicated by each plot are stored as the result (adjustment result) of the adjustment process without exposure in the storage unit 109 in step S402 and collected by the collection unit 110.

FIG. 7 is a graph representing a standard deviation 3σ corresponding to the plurality of plots shown in FIG. 6. The controller 108 may generate data representing the standard deviation 3σ as apparatus specification specific adjustment results in step S503. The controller 108 determines a standard value γ with respect to an apparatus specification α from a measurement condition β including a measurement count (for example, 15) per job and a job execution count (for example, 5), the relative distances corresponding to the relative difference plots in FIG. 6, and the standard deviation 3σ corresponding to the plot in FIG. 7.

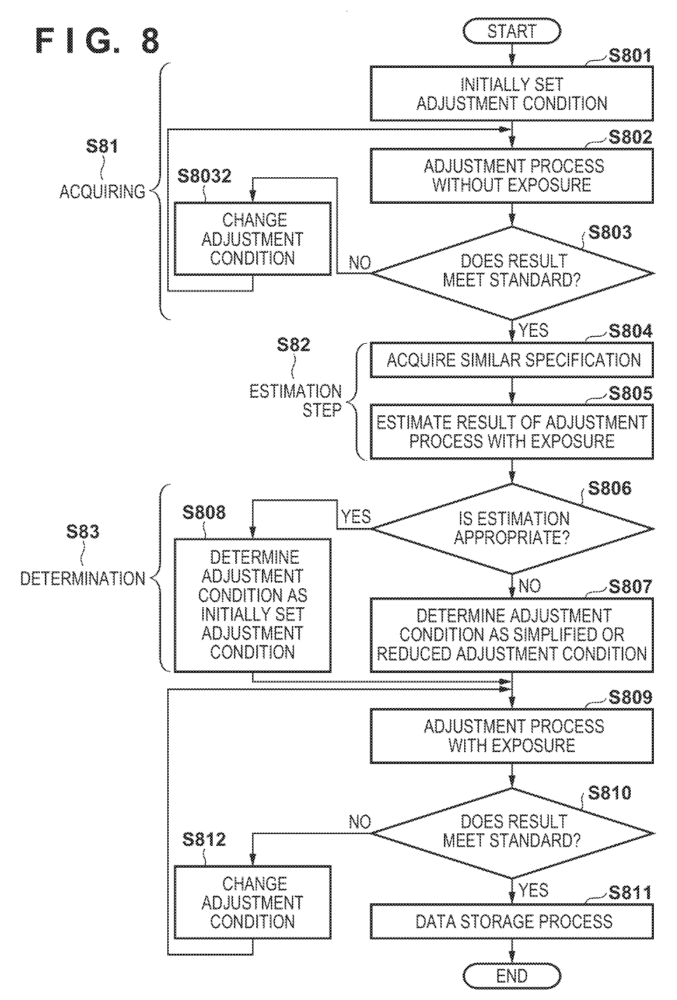

An adjustment process for the apparatus performance of the exposure apparatus will be described with reference to the flowchart of FIG. 8. An adjustment process in the present embodiment can include acquisition step S81 of acquiring an adjustment result indicating the result of an adjustment process without exposure (first adjustment process) executed in the exposure apparatuses (the exposure apparatus 101 and other exposure apparatuses having other apparatus specifications). In addition, the adjustment process in the present embodiment can further include estimation step S82 of estimating the result of an adjustment process (second adjustment process) with exposure performed after the adjustment process without exposure in the exposure apparatus 101. The adjustment process in the present embodiment can further include a determination step of evaluating the estimated data obtained in estimation step S82 based on the adjustment result acquired in acquisition step S81 and determining a condition for an adjustment process with exposure based on the evaluation result.

Acquisition step S81 will be described. In step S801, the controller 108 initially sets an adjustment condition in accordance with the apparatus specification of the exposure apparatus 101 stored in the storage unit 109. As described above, the adjustment condition can include adjustment parameter values for the exposure apparatus. In step S802, the controller 108 executes an adjustment process without exposure in accordance with the adjustment condition initially set in step S801. In step S803, the controller 108 determines whether the result of the adjustment process without exposure in step S802 meets a predetermined standard. If the result of the adjustment process without exposure does not meet the standard, the controller 108 changes the adjustment condition in step S8032 and executes again an adjustment process without exposure in step S802. If the result of the adjustment process without exposure meets the standard, the process shifts to estimation step S82. As described above, acquisition step S81 can include a step of executing an adjustment process without exposure in accordance with an adjustment condition and repeatedly executing an adjustment process without exposure while changing the adjustment condition until the result of the adjustment process without exposure meets the predetermined standard.

Estimation step S82 will be described next. In step S804, the controller 108 acquires, as a similar specification, an apparatus specification having the highest similarity with the apparatus specification of the exposure apparatus 101 from the plurality of apparatus specifications written in the database stored in the storage unit 109. More specifically, the controller 108 compares the apparatus specification of the exposure apparatus 101 with each of the plurality of apparatus specifications written in the database and acquires a matched apparatus specification, if ever, as a similar specification. If there is no matched apparatus specification, the controller 108 acquires an apparatus specification closest to the apparatus specification of the exposure apparatus 101 as a similar specification.

In step S805, the estimation unit 112 refers to, for example, the database stored in the storage unit 109 to specify the result of an adjustment process with exposure corresponding to the similar specification acquired in step S804, thereby obtaining the specified result as an estimation result.

Subsequent steps including determination step S83 will be described next. In step S806, the determination unit 113 evaluates the estimation result in step S82 based on the adjustment result finally obtained in step S802 (evaluation step). For example, the determination unit 113 compares an adjustment result indicating the result of the adjustment process without exposure finally obtained in step S802 with an adjustment result indicating an adjustment process without exposure which corresponds to the similar specification obtained in step S804 in the database (for example, calculates the difference). A specific example of the result of the adjustment process without exposure finally obtained in step S802 can be the standard deviation 3σ (FIG. 7) with respect to the relative difference between measurement results by the alignment optical system 107 in one job. If the calculated difference falls within a predetermined standard value (allowable range), the determination unit 113 evaluates the estimation result as appropriate (for example, no problem in the measurement reproducibility of the alignment optical system 107). Otherwise, the determination unit 113 evaluates the estimation result as inappropriate. The determination unit 113 determines an adjustment condition for an adjustment process with exposure based on the evaluation result (adjustment step). For example, upon evaluating the estimation result as appropriate in an adjustment step, the determination unit 113 determines, in step S808, the adjustment condition for the adjustment process with exposure as an adjustment condition as an initial setting in step S801. Upon evaluating the estimation result as inappropriate, the determination unit 113 determines, in step S807, the condition for the adjustment process with exposure as a simplified or reduced adjustment condition with respect to the adjustment condition initially set in step S801.

The above description is about the contents in determination step S83. According to the above case, the determination unit 113 calculates, in step S806, the difference between the result of the adjustment process without exposure finally obtained in step S802 and the result of the adjustment process without exposure which corresponds to the similar specification obtained in step S804 in the database. Note, however, that the comparison between the results of adjustment processes without exposure may use not a simple difference but an evaluation value including at least one of dispersion, discrepancy, a difference between correlation coefficients, and the like.

In step S809, the controller 108 executes the adjustment process with exposure under the adjustment condition determined in step S807 or S808. The adjustment process with exposure can be the process of performing checking and adjustment of the overlay accuracy at the time of projecting the pattern of the original plate 102 onto the substrate 104 through the projection optical system 103. Consider the standard deviation 3σ (FIG. 7) associated with the relative differences between the measurement results obtained by the alignment optical system 107 in one job in step S802 described above as a specific example of the result of the adjustment process without exposure finally obtained in step S802. In this case, a reduction in adjustment condition can be a reduction in the number of inspection items of parameters associated with the overlay accuracy in the adjustment process with exposure. The simplification of an adjustment condition can be a reduction in the number of substrates used for the inspection of overlay accuracy.

In step S810, the controller 108 determines whether the result of the adjustment process with exposure executed in step S809 meets the predetermined standard (within the allowable range). If the result of the adjustment process with exposure does not meet the standard, the controller 108 changes the adjustment condition in step S812 and performs again the adjustment process with exposure in step S809. If the result of the adjustment process with exposure meets the standard, the process advances to step S811. As described above, the adjustment process can include the step of executing an adjustment process with exposure in accordance with the adjustment condition determined in an adjustment step and repeatedly executing the adjustment process with exposure while changing the adjustment condition until the result of the adjustment process with exposure meets a predetermined standard.

In step S811, the controller 108 saves, in the storage unit 109, the adjustment result as a set of the apparatus specification, the adjustment condition set finally, the result of the adjustment process without exposure, and the result of the adjustment process with exposure. Thereafter, the collection unit 110 transfers the adjustment result stored in the storage unit 109 to the external collection unit 111.

Note that estimated data indicating the estimation result obtained in step S805 may be provided to a customer. Providing the estimated data to the customer makes it possible to implement customer process improvement and the determination of the advantages and disadvantages of adjustment without using any physical resources such as a substrate and a light source (for example, a laser).

As described above, according to the present embodiment, it is possible to shorten the time taken for an adjustment checking operation performed at the time of assembly or maintenance of an exposure apparatus without degrading the apparatus quality.

### SECOND EMBODIMENT

In the first embodiment, an adjustment process without any exposure process is defined as the first adjustment process, and an adjustment process with an exposure process is defined as the second adjustment process. However, it is not essentially necessary to discriminate adjustment processes depending on whether they accompany exposure. The first adjustment process may be an adjustment process with an exposure process, and the second adjustment process may be an adjustment process without any exposure process. Alternatively, both the first adjustment process and the second adjustment process may be processes without exposure, or both the first adjustment process and the second adjustment process may be processes with exposure.

### Embodiment of Article Manufacturing Method

An article manufacturing method according to an embodiment is suitable for manufacturing an article, for example, a microdevice such as a semiconductor device or an element having a microstructure. The article manufacturing method according to the present embodiment can include a forming step of forming an original plate pattern onto a substrate by using the above-described exposure apparatus and a processing step of processing the substrate on which the pattern is formed in the forming step. The manufacturing method further can include other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

According to the present disclosure, it is possible to provide a technique advantageous in satisfying both requirements for a reduction in time associated with an adjustment checking operation performed at the time of assembly or maintenance of a substrate processing apparatus and apparatus quality.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)^{TM}), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-182173, filed October 17, 2024 which is hereby incorporated by reference herein in its entirety.

What is claimed is:

1. A computer-readable storage medium storing a program for causing a computer to execute an adjustment method of adjusting apparatus performance of a substrate processing apparatus, the program causing the computer to perform
acquiring an adjustment result indicating a result of a first adjustment process executed in the substrate processing apparatus,
estimating a result of a second adjustment process performed after the first adjustment process in the substrate processing apparatus based on an apparatus specification of the substrate processing apparatus, and
determining a condition for the second adjustment process based on the adjustment result and an estimation result obtained in the estimating.

2. The storage medium according to claim 1, wherein the estimating includes
acquiring, as a similar specification, an apparatus specification having highest similarity with the apparatus specification of the substrate processing apparatus by referring to a database indicating results of the apparatus specification specific first and second adjustment processes obtained based on actual results of the first and second adjustment processes performed in a plurality of substrate processing apparatuses with different apparatus specifications, and
specifying a result of the second adjustment process corresponding to the similar specification by referring to the database and obtaining the specified result of the second adjustment process as the estimation result.

3. The storage medium according to claim 2, wherein the program causes the computer to perform
collecting a plurality of apparatus specifications,
collecting results of a plurality of first adjustment processes as a set of results of the first adjustment processes respectively corresponding to the plurality of apparatus specifications and results of a plurality of second adjustment processes as a set of results of the second adjustment processes respectively corresponding to the plurality of apparatus specifications, and
generating the database based on the plurality of apparatus specifications, the results of the plurality of first adjustment processes, and the results of the plurality of second adjustment processes.

4. The storage medium according to claim 1, wherein the acquiring includes
initially setting an adjustment condition including an adjustment parameter of the substrate processing apparatus in accordance with the apparatus specification, and
executing the first adjustment process in accordance with the adjustment condition and repeatedly executing the first adjustment process while changing the adjustment condition until a result of the first adjustment process meets a predetermined standard.

5. The storage medium according to claim 2, wherein the determining the condition includes
evaluating the estimation result as appropriate if an evaluation value between the adjustment result and an adjustment result indicating a result of the first adjustment process corresponding to the similar specification in the database falls within an allowable range and, otherwise evaluating the estimation result as inappropriate, and
determining an adjustment condition for the second adjustment process as an initially set adjustment condition if the estimation result is evaluated as appropriate and determining an adjustment condition for the second adjustment process as an adjustment condition obtained by simplifying or reducing the initially set adjustment condition if the evaluation result is evaluated as inappropriate.

6. The storage medium according to claim 5, wherein the reducing the adjustment condition is reducing a parameter inspection item in the second adjustment process.

7. The storage medium according to claim 5, wherein the simplifying the adjustment condition is reducing the number of substrates used in the second adjustment process.

8. The storage medium according to claim 5, wherein the evaluation value includes at least one of a difference, dispersion, discrepancy, and a difference between correlation coefficients, between the adjustment result and an adjustment result indicating a result of the first adjustment process corresponding to the similar specification in the database.

9. The storage medium according to claim 5, wherein the program causes the computer to further execute executing the second adjustment process in accordance with the adjustment condition set in the determining the adjustment condition and repeatedly executing the second adjustment process while changing the adjustment condition until a result of the second adjustment process meets a predetermined standard.

10. The storage medium according to claim 1, wherein the determining the condition evaluates the estimation result based on the adjustment result and determines a condition for the second adjustment process based on a result of the evaluation.

11. The storage medium according to claim 1, wherein the substrate processing apparatus is an exposure apparatus that exposes a substrate to light,
the first adjustment process is an adjustment process without exposure, and
the second adjustment process is an adjustment process with exposure which is performed after the first adjustment process in the exposure apparatus.

12. An information processing apparatus that includes a processor and a memory and causes the processor to determine a condition for an adjustment process of adjusting apparatus performance of a substrate processing apparatus,
wherein the processor executes
acquiring an adjustment result indicating a result of a first adjustment process executed in the substrate processing apparatus,
estimating a result of a second adjustment process performed after the first adjustment process in the substrate processing apparatus based on an apparatus specification of the substrate processing apparatus, and
determining a condition for the second adjustment process based on the adjustment result and an estimation result obtained in the estimating.

13. A substrate processing apparatus that processes a substrate, the apparatus comprising
a controller configured to control an adjustment process of adjusting apparatus performance of the substrate processing apparatus,
wherein the controller is configured to perform, in the adjustment process,
executing a first adjustment process,
estimating a result of a second adjustment process performed after the first adjustment process based on an apparatus specification of the substrate processing apparatus,
determining a condition for the second adjustment process based on an adjustment result indicating a result of the first adjustment process and an estimation result obtained in the estimating, and
executing the second adjustment process in accordance with the condition determined in the determining the condition.

14. The apparatus according to claim 13, wherein the substrate processing apparatus is an apparatus configured to perform a process of forming a pattern on the substrate.

15. An article manufacturing method comprising:
forming a pattern on a substrate by using a substrate processing apparatus defined in claim 14; and
processing the substrate on which the pattern is formed,
wherein an article is manufactured from the substrate having undergone the processing.
